(19) United States
(12) Patent Application Publication
(10) Pub. No.: US 2017/0371007 A1
(43) Pub. Date: Dec. 28, 2017

(54) BILAYER HARDMASK

(71) Applicant: Allegro Microsystems, LLC, Worcester, MA (US)

(72) Inventors: Paul Anderson, Eden Prairie, MN (US); Thomas Francis, Wayzata, MN (US)

(73) Assignee: Allegro Microsystems, LLC, Worcester, MA (US)

(21) Appl. No.: 15/195,124

(22) Filed: Jun. 28, 2016

(51) Int. Cl. G01R 33/09; H01L 43/02; H01L 43/08; H01L 43/12

(52) U.S. Cl. CPC G01R 33/093; H01L 43/12; G01R 33/098; H01L 43/02; H01L 43/08

(57) ABSTRACT

In one aspect, a method includes etching a magnetic field sensor element covered by a bilayer hardmask. In another aspect, a method includes depositing a silicon nitride on a magnetic field sensor element, depositing a silicon dioxide on the silicon nitride, forming the bilayer mask by etching the silicon dioxide and etching the magnetic field sensor element partially covered by the bilayer hardmask. The magnetic field sensor element includes one of a giant magnetoresistance (GMR) element, a tunneling magnetoresistance (TMR) element or a magnetic tunnel junction (MTJ). The bilayer mask includes the silicon dioxide and the silicon nitride. In a further aspect, a sensor includes a magnetic field sensor element that includes one of a GMR element, a TMR element or a MTJ. The sensor also includes a bilayer hardmask disposed on the magnetic field sensor element. The bilayer mask includes a silicon dioxide and a silicon nitride.

### BACKGROUND

In semiconductor device fabrication, a hardmask is a material used in an etching process. Typically, a hardmask covers portions of a surface not to be etched while the portion of the surface exposed by the mask are etched. A hardmask does not include a polymer or soft organic materials such as photoresist, which can under certain conditions be etched away during an etching process such as plasma etching.

Etch selectivity between two materials is a ratio between their etching rates at identical plasma conditions. In one example, a high etch selectivity is typically related to a high etching rate ratio between chemically different materials or between an etched layer and an underlying layer (i.e., the etched layer is etched at a higher rate than the underlying layer) so that, in some examples, the underling layer is undamaged.

### SUMMARY

In one aspect, a method includes etching a magnetic field sensor element covered by a bilayer hardmask. This aspect may include one or more of the following features. The method may also include depositing a silicon nitride on the magnetic field sensor element, depositing a silicon dioxide on the silicon nitride and forming the bilayer mask by etching the silicon dioxide, wherein the bilayer mask comprises the silicon dioxide and the silicon nitride. Depositing a silicon nitride on the magnetic field sensor element may include depositing silicon nitride that is about 50 to 750 Angstroms thick. Depositing a silicon dioxide on the silicon nitride may include depositing silicon dioxide that is about 1,000 to 10,000 Angstroms thick. Forming the bilayer mask by etching the silicon dioxide may include forming the mask using photolithography. The method may include depositing a passivation layer on the bilayer mask and the magnetic field sensing element. Depositing the passivation layer on the bilayer mask and the magnetic field sensing element may include depositing silicon nitride. The method may include depositing the magnetic field sensing element on a silicon dioxide. Depositing the magnetic field sensing element may include depositing one of a giant magnetoresistance (GMR) element, a tunneling magnetoresistance (TMR) element or a magnetic tunnel junction (MTJ).

In another aspect, a method includes depositing a silicon nitride on a magnetic field sensor element, depositing a silicon dioxide on the silicon nitride, forming the bilayer mask by etching the silicon dioxide and etching the magnetic field sensor element partially covered by the bilayer hardmask. The magnetic field sensor element includes one of a giant magnetoresistance (GMR) element, a tunneling magnetoresistance (TMR) element or a magnetic tunnel junction (MTJ). The bilayer mask includes the silicon dioxide and the silicon nitride. This aspect may include one or more of the following features. Depositing a silicon nitride on the magnetic field sensor element may include depositing silicon nitride that is about 50 to 750 Angstroms thick. Depositing a silicon dioxide on the silicon nitride may include depositing silicon dioxide that is about 1,000 to 10,000 Angstroms thick. Forming the bilayer mask by etching the silicon dioxide may include forming the mask using photolithography. The method may include depositing a passivation layer on the bilayer mask and the magnetic field sensing element. Depositing the passivation layer on the bilayer mask and the magnetic field sensing element may include depositing silicon nitride.

In a further aspect, a sensor includes a magnetic field sensor element that includes one of a giant magnetoresistance (GMR) element, a tunneling magnetoresistance (TMR) element or a magnetic tunnel junction (MTJ). The sensor also includes a bilayer hardmask disposed on the magnetic field sensor element. The bilayer mask includes a silicon dioxide and a silicon nitride. This aspect may include one or more of the following features. The silicon nitride may be about 50 to 750 Angstroms thick. The silicon dioxide may be about 1,000 to 10,000 Angstroms thick.

### DESCRIPTION OF THE DRAWINGS

FIG. 1 is a flowchart of an example of a process to use a bilayer hardmask to fabricate a magnetic field sensor; and

FIGS. 2 to 6 are block diagrams of an example to use a bilayer hardmask to fabricate a magnetic field sensor.

### DETAIL DESCRIPTION

Described herein are techniques to fabricate a magnetic field sensor using a bilayer hardmask. In one particular example, the bilayer hardmask includes silicon nitride and silicon dioxide.

As used herein, the term “magnetic field sensor” is used to describe a variety of electronic elements that can sense a magnetic field that include one or more magnetic field sensing elements. The magnetic field sensing element may be, but is not limited to an MR element. As is known, there are different types of MR elements, which include a semiconductor MR element such as a giant magnetoresistance (GMR) element, a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

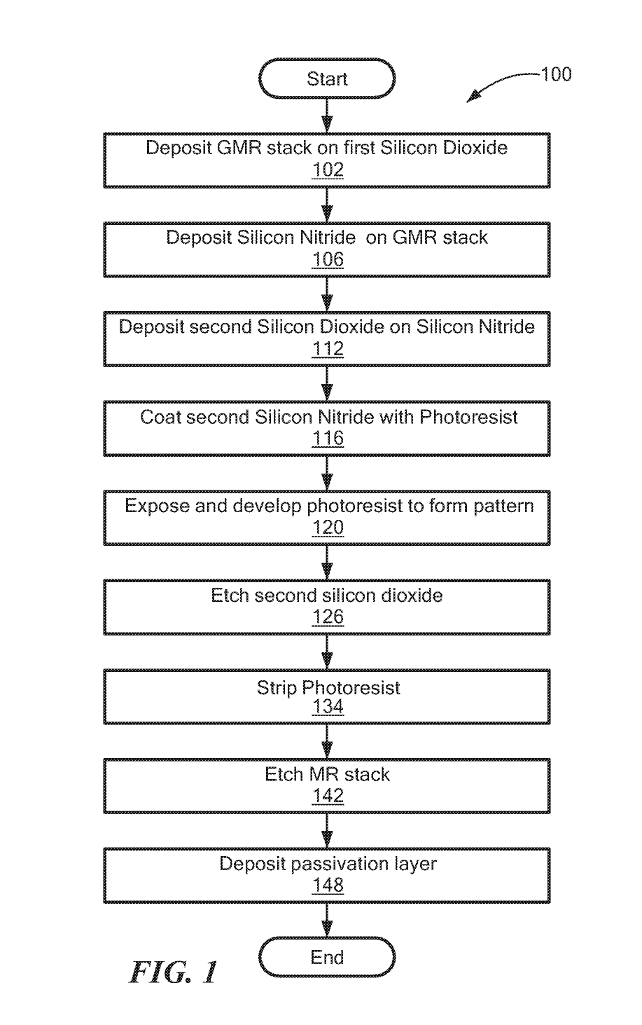

Referring to FIGS. 1 to 6, a process 100 is an example of a process to use a bilayer hardmask to fabricate a magnetic sensor. Though FIGS. 1 to 6 describe fabricating a GMR, other magnetic field sensing elements may be fabricated using the process 100.

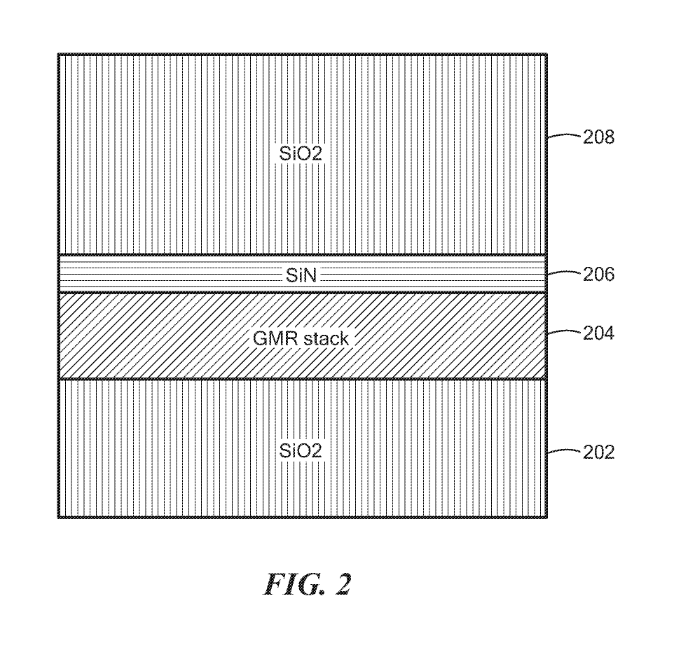

In process 100, a GMR stack is deposited on a first silicon dioxide (102), a silicon nitride is deposited on the GMR stack (106) and a second silicon nitride is deposited on the silicon nitride (112). For example, a GMR stack 204 is deposited on a silicon dioxide 202 on a silicon wafer (not shown), a silicon nitride 206 is deposited on the GMR stack 204; and a silicon dioxide 208 is deposited on the silicon nitride 206 (FIG. 2). In one particular example, the silicon nitride 206 is about 50 to 750 Angstroms thick. In one particular example, the silicon dioxide 208 is about 1,000 to 10,000 Angstroms thick. In one example, the GMR stack 202 includes a plurality of layers. The plurality of layers, for example, may include an antiferromagnetic layer, a first pinned layer, a first non-magnetic layer, a second pinned layer, a second non-magnetic layer and a free layer. In one particular example of an MR element, the antiferromagnetic layer includes PtMn, the first and second pinned layers include CoFe, the first and second non-magnetic layers include a selected one of Ir and Ru, and the free layer includes NiFe. In other example, other layers and materials may be provided in a GMR stack.

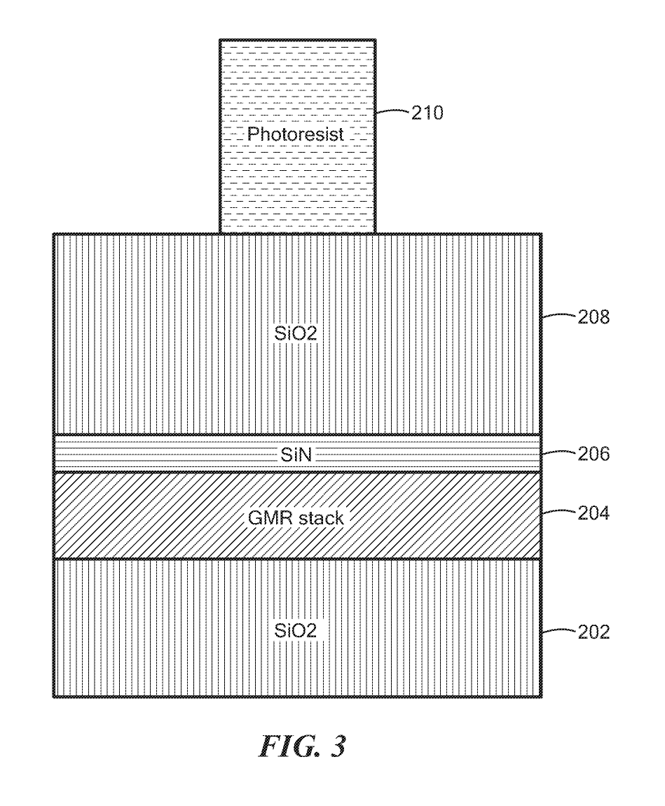

The second silicon dioxide is coated with a photoresist (116) and the photoresist is exposed to ultraviolet light and developed to form a pattern (120). For example, a photoresist 210 is used to coat the silicon dioxide 208 (FIG. 3). In other examples, the silicon dioxide 208 is coated with bottom-anti-reflective coating (BARC) instead of the photoresist 210.

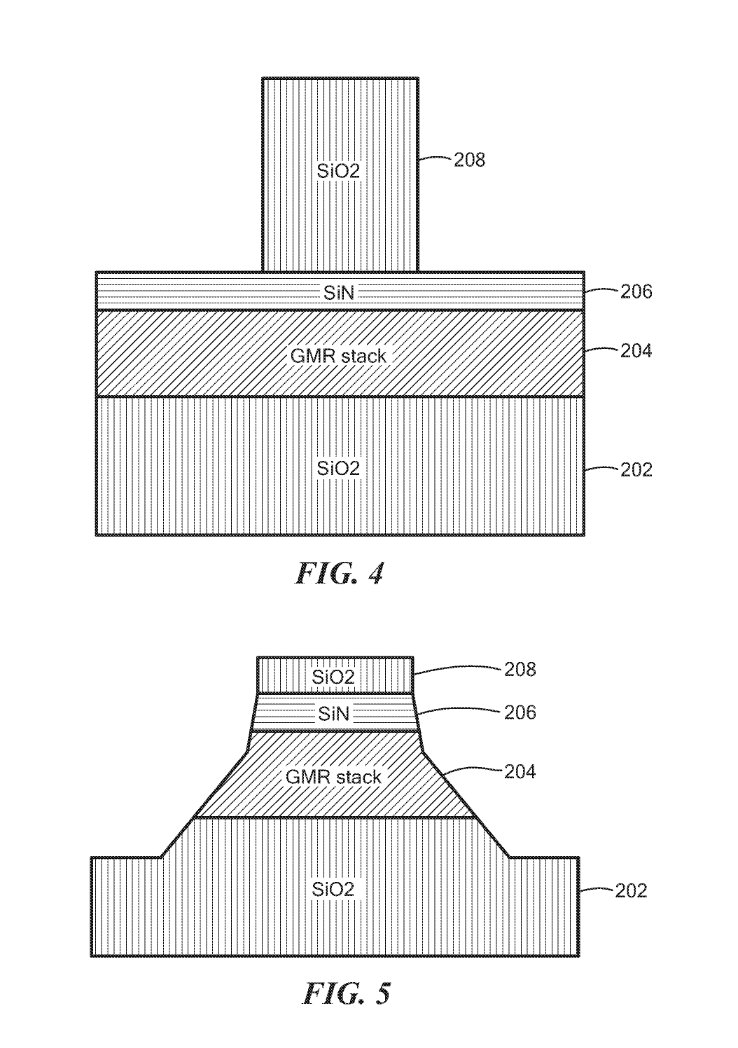

The second silicon dioxide is etched (126). For example, the silicon dioxide 208 is etched using high etch selectivity to remove the silicon dioxide 208 but not to remove the silicon nitride 206 (FIG. 4).

The photoresist is stripped (134). For example, the photoresist 210 is removed using dry or wet stripping techniques (FIG. 5). A bilayer mask remains, which includes the silicon nitride 206 and the silicon dioxide 208 on the GMR stack 204.

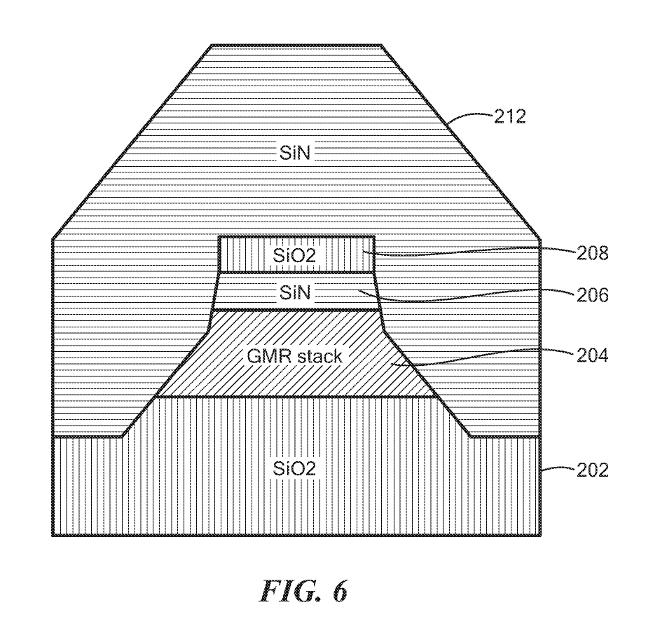

The GMR is etched (142) and a passivation layer is added (148). In one example, dry etching is used. In other examples, ion beam etching is used to pattern the GMR stack and to cease etching prior to hitting the GMR stack 204 or to cease etching on a top layer of the GMR stack 204. In one example, a silicon nitride layer 212 is deposited on top of the silicon dioxide 208, the silicon nitride 206, the GMR stack 204 and the silicon dioxide 202 (FIG. 6).

Elements of different embodiments described herein may be combined to form other embodiments not specifically set forth above. Various elements, which are described in the context of a single embodiment, may also be provided separately or in any suitable subcombination. Other embodiments not specifically described herein are also within the scope of the following claims.

What is claimed is:

1. A method comprising:
depositing a magnetic field sensor element on a substrate; and
etching the magnetic field sensor element covered by a bilayer hardmask.

2. The method of claim 1, further comprising:
depositing a silicon nitride on the magnetic field sensor element;
depositing a silicon dioxide on the silicon nitride; and
forming the bilayer mask by etching the silicon dioxide, wherein the bilayer mask comprises the silicon dioxide and the silicon nitride.

3. The method of claim 2, wherein depositing a silicon nitride on the magnetic field sensor element comprises depositing silicon nitride that is about 50 to 750 Angstroms thick.

4. The method of claim 3, wherein depositing a silicon dioxide on the silicon nitride comprises depositing silicon dioxide that is about 1,000 to 10,000 Angstroms thick.

5. The method of claim 2, wherein forming the bilayer mask by etching the silicon dioxide comprises forming the mask using photolithography.

6. The method of claim 1, further comprising depositing a passivation layer on the bilayer mask and the magnetic field sensing element.

7. The method of claim 6, wherein depositing the passivation layer on the bilayer mask and the magnetic field sensing element comprises depositing silicon nitride.

8. The method of claim 1, wherein depositing a magnetic field sensor element on a substrate comprises depositing the magnetic field sensing element on a silicon dioxide.

9. The method of claim 8, wherein depositing the magnetic field sensing element comprises depositing one of a giant magnetoresistance (GMR) element, a tunneling magnetoresistance (TMR) element or a magnetic tunnel junction (MTJ).

10. A method comprising:
depositing a silicon nitride on a magnetic field sensor element, the magnetic field sensor element comprises one of a giant magnetoresistance (GMR) element, a tunneling magnetoresistance (TMR) element or a magnetic tunnel junction (MTJ);
depositing a silicon dioxide on the silicon nitride;
forming the bilayer mask by etching the silicon dioxide, wherein the bilayer mask comprises the silicon dioxide and the silicon nitride; and
etching the magnetic field sensor element partially covered by the bilayer hardmask.

11. The method of claim 10, wherein depositing a silicon nitride on the magnetic field sensor element comprises depositing silicon nitride that is about 50 to 750 Angstroms thick.

12. The method of claim 11, wherein depositing a silicon dioxide on the silicon nitride comprises depositing silicon dioxide that is about 1,000 to 10,000 Angstroms thick.

13. The method of claim 10, wherein forming the bilayer mask by etching the silicon dioxide comprises forming the mask using photolithography.

14. The method of claim 10, further comprising depositing a passivation layer on the bilayer mask and the magnetic field sensing element.

15. The method of claim 14, wherein depositing the passivation layer on the bilayer mask and the magnetic field sensing element comprises depositing silicon nitride.

16. A sensor comprising
a magnetic field sensor element comprising one of a giant magnetoresistance (GMR) element, a tunneling magnetoresistance (TMR) element or a magnetic tunnel junction (MTJ); and
a bilayer hardmask disposed on the magnetic field sensor element, the bilayer mask comprising a silicon dioxide and a silicon nitride.

17. The sensor of claim 16, wherein the silicon nitride is about 50 to 750 Angstroms thick.

18. The sensor of claim 16, wherein the silicon dioxide is about 1,000 to 10,000 Angstroms thick.
